(19) United States
(12) Patent Application Publication
(10) Pub. No.: US 2011/0030771 A1
(43) Pub. Date: Feb. 10, 2011

(54) Organic photosensitive optoelectronic device with near-infrared sensitivity

(76) Inventors: Stephen R. Forrest, Ann Arbor, MI (US); Rhonda F. Bailey-Salzman, Ann Arbor, MI (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/984,378

(22) Filed: Nov. 16, 2007

Related U.S. Application Data
(60) Provisional application No. 60/960,442, filed on Sep. 28, 2007.
(60) Provisional application No. 60/960,730, filed on Oct. 11, 2007.

(51) Int. Cl. H01L 51/44; H01L 51/46; H01L 51/48

(52) U.S. Cl. 136/256; 257/40; 438/82; 257/E51.012; 257/E51.041

(57) ABSTRACT

An organic photosensitive optoelectronic device having near infrared sensitivity and the method of fabrication thereof are described. The organic photosensitive optoelectronic device comprises a first electrode and a second electrode and organic photoactive materials comprising ClAlPc.

### CROSS REFERENCE TO RELATED APPLICATIONS

This application claims the benefits of U.S. Provisional Application Nos. 60/960,442 filed Sep. 28, 2007 and 60/960,730 filed Oct. 11, 2007, the disclosures of which are herein incorporated by reference.

### UNITED STATES GOVERNMENT RIGHTS

This invention was made with government support under F9550-06-1-0254 and F9550-07-1-0364 awarded by the U.S. Air Force Office of Scientific Research. The government has certain rights in this invention.

### JOINT RESEARCH AGREEMENT

The claimed invention was made by, on behalf of, and/or in connection with one or more of the following parties to a joint university-corporation research agreement: Princeton University, University of Michigan, and Global Photonic Energy Corporation. The agreement was in effect on and before the date the claimed invention was made, and the claimed invention was made as a result of activities undertaken within the scope of the agreement.

### FIELD OF THE INVENTION

Embodiments of the present invention generally relates to organic photosensitive optoelectronic devices. More specifically, the embodiments are directed to organic photosensitive optoelectronic devices having near infrared sensitivity.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into an electrical signal or electricity. Solar cells, also called photovoltaic (“PV”) devices, are a type of photosensitive optoelectronic device that is specifically used to generate electrical power. Photoconductor cells are a type of photosensitive optoelectronic device that are used in conjunction with signal detection circuitry which monitors the resistance of the device to detect changes due to absorbed light. Photodetectors, which may receive an applied bias voltage, are a type of photosensitive optoelectronic device that are used in conjunction with current detecting circuits which measures the current generated when the photodetector is exposed to electromagnetic radiation.

These three classes of photosensitive optoelectronic devices may be distinguished according to whether a rectifying junction is present and also according to whether the device is operated with an external applied voltage, also known as a bias or bias voltage. A photoconductor cell does not have a rectifying junction and is normally operated with a bias. A PV device has at least one rectifying junction and is operated with no bias. A photodetector has at least one rectifying junction and is usually but not always operated with a bias.

As used herein, the term “rectifying” denotes, inter alia, that an interface has an asymmetric conduction characteristic, i.e., the interface supports electronic charge transport preferably in one direction. The term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct (i.e., transport) electric charge in a material. The term “photoconductive material” refers to semiconductor materials which are utilized for their property of absorbing electromagnetic radiation to generate electric charge carriers. As used herein, “top” means furthest away from the substrate, while “bottom” means closest to the substrate. There may be intervening layers (for example, if a first layer is “on” or “over” a second layer), unless it is specified that the first layer is “in physical contact with” or “directly on” the second layer; however, this does not preclude surface treatments (e.g., exposure of the first layer to hydrogen plasma).

When electromagnetic radiation of an appropriate energy is incident upon an organic semiconductor material, a photon can be absorbed to produce an excited molecular state. In organic photoconductive materials, the generated molecular state is generally believed to be an “exciton,” i.e., an electron-hole pair in a bound state which is transported as a quasi-particle. An exciton can have an appreciable life-time before geminate recombination (“quenching”), which refers to the original electron and hole recombining with each other (as opposed to recombination with holes or electrons from other pairs). To produce a photocurrent, the electron-hole forming the exciton are typically separated at a rectifying junction.

In the case of photosensitive devices, the rectifying junction is referred to as a photovoltaic heterojunction. Types of organic photovoltaic heterojunctions include a donor-acceptor heterojunction formed at an interface of a donor material and an acceptor material, and a Schottky-barrier heterojunction formed at the interface of a photoconductive material and a metal.

FIG. 1 is an energy-level diagram illustrating an example donor-acceptor heterojunction. In the context of organic materials, the terms “donor” and “acceptor” refer to the relative positions of the Highest Occupied Molecular Orbital (“HOMO”) and Lowest Unoccupied Molecular Orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material.

As used herein, a first HOMO or LUMO energy level is “greater than” or “higher than” a second HOMO or LUMO energy level if the first energy level is closer to the vacuum energy level 10. A higher HOMO energy level corresponds to an ionization potential (“IP”) having a smaller absolute energy relative to a vacuum level. Similarly, a higher LUMO energy level corresponds to an electron affinity (“EA”) having a smaller absolute energy relative to vacuum level. On a conventional energy level diagram, with the vacuum level at the top, the LUMO energy level of a material is higher than the HOMO energy level of the same material.

After absorption of a photon 6 in the donor 152 or the acceptor 154 creates an exciton 8, the exciton 8 disassociates at the rectifying interface. The donor 152 transports the hole (open circle) and the acceptor 154 transports the electron (dark circle).

A significant property in organic semiconductors is carrier mobility. Mobility measures the ease with which a charge carrier can move through a conducting material in response to an electric field. In the context of organic photosensitive devices, a material that conducts preferentially by electrons due to a high electron mobility may be referred to as an electron transport material. A material that conducts preferentially by holes due to a high hole mobility may be referred to as a hole transport material. A layer that conducts preferentially by electrons, due to mobility and/or position in the device, may be referred to as an electron transport layer (“ETL”). A layer that conducts preferentially by holes, due to mobility and/or position in the device, may be referred to as a hole transport layer (“HTL”). Preferably, but not necessarily, an acceptor material is an electron transport material and a donor material is a hole transport material.

How to pair two organic photoconductive materials to serve as a donor and an acceptor in a photovoltaic heterojunction based upon carrier mobilities and relative HOMO and LUMO levels is well known in the art, and is not addressed here.

For additional background explanation and description of the state of the art for organic photosensitive devices, including their general construction, characteristics, materials, and features, U.S. Pat. No. 6,657,378 to Forrest et al., U.S. Pat. No. 6,580,027 to Forrest et al., and U.S. Pat. No. 6,352,777 to Bulovic et al. are incorporated herein by reference.

PV devices may be optimized for maximum electrical power generation under standard illumination conditions (i.e., Standard Test Conditions which are 1000 W/m², AM1.5 spectral illumination), for the maximum product of photocurrent times photovoltage. The power conversion efficiency (“PCE”), η_{P}, of such a cell under standard illumination conditions depends on (1) the current under zero bias, i.e., the short-circuit current density J_{SC}, (2) the photovoltage under open circuit conditions, i.e., the open circuit voltage V_{OC}, and (3) the fill factor, FF via

ηₚ=(J_{sc}×V_{oc}×FF)/Pₒ (1)

where Pₒ is the incident optical power.

To achieve high power output, solar devices must take advantage of as much of the solar spectrum as possible as the photons absorbed by a solar cell directly impacts the power output. The solar spectrum includes invisible ultraviolet (UV) light, the visible spectrum of colors—violet, indigo, blue, green, yellow, orange and red—and the invisible infrared or IR spectrum. Solar radiation includes wavelengths as short as 300 nanometers (nm) and as long as 4,045 nm or ˜4 microns. The amount of incoming photons across the UV, visible, and IR spectrums is about 3%, 45%, and 52%, respectively.

A material's ability to efficiently absorb solar light across a broad range of wavelengths directly impacts the PCE potential of the same solar cell. The PCE performance of silicon is as a result of a nearly optimal bandgap (at 1.1 eV) for absorbing solar light. Silicon devices efficiently absorb and convert solar energy up to about 1,050 nm, covering approximately 75% of the total photon flux from the sun. The visible-light spectrum covers a range of 390 nm (violet) to ˜750 nm (red). Near-infrared begins at about 750 nm and extends to 1,400 nm, or 1.4 microns. Approximately 85% of the total photon flux from the sun is between 300 nm and 1,400 nm.

Organic photovoltaic cells have great promise to become a viable alternative to the existing solar cell technologies, dominated by silicon-based devices. However, their efficiencies are currently too low to compete effectively with silicon-based devices. The record efficiencies for laboratory based organic photovoltaic cells is 5.7%, which is roughly half the efficiency of commercial amorphous silicon based PV cells. See Yang et al., Controlled Growth of a Molecular Bulk Heterojunction Photovoltaic Cell, Nature Materials, 2005, 4(1), 37-41.

A major challenge preventing small molecule-based organic photovoltaic cells from achieving high efficiencies is the lack of materials absorbing in the IR that allow for broad solar spectral coverage. Copper phthalocyanine (“CuPc”), a commonly-used donor material in organic photovoltaics, has an absorption spectrum that falls off at wavelengths of λ>700 nm. See Tang, Two Layer Organic Photovoltaic Cells, Applied Physics Letters, 1986, 48(3), 183-185. Recently, the use of tin phthalocyanine, which has absorption peaks at λ=740 and λ=860 nm, has resulted in an IR-sensitive organic photovoltaic with a power conversion efficiency of η_{P}=1.0±0.1% under simulated AM1.5 G, 1 sun illumination. See Rand, et al., Organic Solar Cells with Sensitivity Extending into the Near Infrared, Applied Physics Letters, 2005, 87, 233508. Furthermore, polymers in bulk heterojunction OPVs have demonstrated η_{P}=0.7% for materials with absorption to λ=1000 nm, and η_{P}≦3.2% for materials with absorption extending to λ≦850 nm. See Wang, et al., Polymer Solar Cells with Low-Bandgap Polymers Blended with C₇₀-Derivative Give Photocurrent at 1 μm, Thin Solid Films, 2006, 511, 576-580; Zhang, et al., Low-Bandgap Alternating Fluorene Copolymer/Methanofullerene Heterojunctions in Efficient Near-Infrared Polymer Solar Cells, Advanced Materials, 2006, 18(16), 2169-2173; Mühlbacher, et al., High Photovoltaic Performance of a Low-Bandgap Polymer, Advanced Materials, 2006, 18(21), 2884-2889.

An approach to increasing η_{P} of organic photovoltaic cells involves finding materials combinations with a high open circuit voltage (V_{OC}). Recently, the donor molecule, boron subphthalocyanine chloride (“SubPc”) in combination with the acceptor C₆₀ resulted in a cell with V_{OC}=0.98 V. This increase in V_{OC} with respect to conventional CuPc-based cells results from the decrease of the highest occupied molecular orbital (HOMO) energy relative to vacuum of SubPc compared to that of CuPc. See Mutolo et al., Enhanced Open-Circuit Voltage in Subphthalocvanine/C₆₀ Organic Photovoltaic Cells, Journal of American Chemistry Society, 2006, 128(25), 8108-8109; Rand and Burk, Offset Energies at Organic Semiconductor Heterojunctions and Their Influence on the Open-Circuit Voltage of Thin-Film Solar Cells, Physical Review B, 2007, 75, 115327.

Chloroaluminum phthalocyanine (“ClAlPc”) has an absorption peak at λ=755 nm, extending the cell photoresponse into the near IR. Previous work with ClAlPc has disclosed a single heterojunction organic photovoltaic with low efficiency (η_{P}≈0.035%), partially attributed to the low purity materials used and hydration of ClAlPc. See Whitlock et al., Investigations of Materials and Device Structures for Organic Semiconductor Solar Cells, Optical Engineering, 1993, 32(8), 1921-1934. ClAlPc has also been used in Au/ClAlPc/Si cells that do not involve heterojunctions. See Yanagi et al., Improved Photovoltaic Properties for Au/AlPcCl/n-Si Solar Cells with Morphology-Controlled AlPcCl Deposition, Journal of Applied Physics, 1994, 75(1), 568-576.

### SUMMARY

According to embodiments of the present invention using ClAlPc as a donor in a double heterojunction organic photovoltaic, improved materials choice and device processing techniques allow for the construction of organic photovoltaic cells with high open circuit voltage and high PCE.

One of the embodiments of the present invention provides an organic photosensitive optoelectronic device comprising:

(i) first electrode and second electrode, wherein at least one of the first electrode and the second electrode is transparent;

(ii) organic photoactive materials disposed between the first electrode and the second electrode, comprising:

(a) a first organic semiconductor material; and

(b) a second organic semiconductor material,

wherein the first organic semiconductor material comprises at least one donor material relative to the second organic semiconductor material with the second organic semiconductor material comprising at least one acceptor material, or the first organic semiconductor material comprises at least one acceptor material relative to the second organic semiconductor material with the second organic semiconductor material comprising at least one donor material, wherein the at least one donor material comprises ClAlPc, and wherein the first organic semiconductor material is in direct contact with the second organic semiconductor material; and

(iii) at least one exciton blocking layer between the two electrodes and adjacent to at least one of the two electrodes.

Another embodiment of the present invention also provides a method of fabricating the organic photosensitive optoelectronic device comprising:
(I) depositing a first organic semiconductor material on a first electrode;
(II) depositing a second organic semiconductor material on the product of step (I);
(III) depositing a second electrode on the product of step (II),
wherein the first organic semiconductor material comprises at least one donor material relative to the second organic semiconductor material with the second organic semiconductor material comprising at least one acceptor material, or the first organic semiconductor material comprises at least one acceptor material relative to the second organic semiconductor material with the second organic semiconductor material comprising at least one donor material, wherein the at least one donor material comprises ClAlPc; and
(IV) putting at least one exciton blocking layer between the two electrodes and adjacent to at least one of the two electrodes.

### BRIEF DESCRIPTION OF THE DRAWINGS

FIG. 1 is an energy level diagram illustrating a donor-acceptor heterojunction.

FIG. 2 illustrates an organic photosensitive device including a donor-acceptor heterojunction.

FIG. 3 illustrates a donor-acceptor bilayer forming a planar heterojunction.

FIG. 4 illustrates a hybrid heterojunction including a mixed heteroj unction between a donor layer and an acceptor layer.

FIG. 5 illustrates a bulk heterojunction.

FIG. 6 illustrates an organic photosensitive device including a Schottky-barrier heterojunction.

FIG. 7 illustrates tandem photosensitive cells in series.

FIG. 8 illustrates tandem photosensitive cells in parallel.

FIG. 9(a) shows molecular structural formula of ClAlPc. FIG. 9(b) shows atomic force micrograph of a 200 Å thick film of ClAlPc grown at 0.5 Å/s on an indium tin oxide substrate. Corresponding root mean square surface roughness was 53 Å. The vertical axis is on a scale of 40 nm/division and the horizontal axes are 0.2 μm/division.

FIG. 10 shows normalized absorption spectra for ClAlPc and CuPc. ClAlPc has a peak at a wavelength of =755 nm, redshifted from that of CuPc by approximately 135 nm. External quantum efficiency is also shown for a planar double heterojunction organic photovoltaic cell with the structure indium tin oxide/200 Å ClAlPc/400 Å C₆₀/100 Å bathocuproine/Ag in which the ClAlPc was grown at a rate of 0.5 Å/s.

FIG. 11(a) shows current density vs. voltage in the dark and under various simulated AM 1.5 G illumination intensities for the structure indium tin oxide/200 Å ClAlPc/400 Å C₆₀/100 Å bathocuprine/Ag where the ClAlPc was grown at a rate of 0.5 Å/s. FIG. 11(b) shows power conversion efficiency η_{P}, open-circuit voltage V_{OC}, and fill factor FF vs. incident optical power density P₀ for the same device as in FIG. 11(a).

FIG. 12 shows some of the performances of ITO/CIAlPc (200 Å at 0.5 Å/s)/C₆₀ (400 Å)BCP (100 Å)/Ag.

FIG. 13 shows performance variation with ClAlPc growth rate.

FIG. 14 shows the relationship between dark current and the ClAlPc growth rate.

The figures are not necessarily drawn to scale.

### DETAILED DESCRIPTION

As used herein, the term “organic” includes polymeric materials as well as small molecule organic materials that may be used to fabricate organic optoelectronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule.” In general, a small molecule has a defined chemical formula with a molecular weight that is the same from molecule to molecule, whereas a polymer has a defined chemical formula with a molecular weight that may vary from molecule to molecule. As used herein, “organic” includes metal complexes of hydrocarbyl and heteroatom-substituted hydrocarbyl ligands.

The electrodes used in a photosensitive optoelectronic device are shown in U.S. patent application Ser. No. 09/136,342, incorporated herein by reference. When used herein, the term “electrode” refers to layers that provide a medium for delivering photogenerated power to an external circuit or providing a bias voltage to the device. That is, an electrode provides the interface between the photoactive regions of an organic photosensitive optoelectronic device and a wire, lead, trace or other means for transporting the charge carriers to or from the external circuit.

In a photosensitive optoelectronic device, it is desirable to allow the maximum amount of ambient electromagnetic radiation from the device exterior to be admitted to the photoactive interior region. That is, the electromagnetic radiation must reach a photoconductive layer, where it can be converted to electricity by photoconductive absorption. This often dictates that preferably, at least one of the electrodes should be minimally absorbing and minimally reflecting of the incident electromagnetic radiation. That is, such an electrode should be substantially transparent. The opposing electrode may be a reflective material so that light which has passed through the cell without being absorbed is reflected back through the cell. As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some, but less that 50% transmission of ambient electromagnetic radiation in relevant wavelengths are said to be “semi-transparent”.

The electrodes are preferably composed of metals or “metal substitutes”. Herein the term “metal” is used to embrace both materials composed of an elementally pure metal, e.g., Mg, and also metal alloys which are materials composed of two or more elementally pure metals, e.g., Mg and Ag together, denoted Mg:Ag. Here, the term “metal substitute” refers to a material that is not a metal within the normal definition, but which has the metal-like properties that are desired in certain appropriate applications. Commonly used metal substitutes for electrodes and charge transfer layers would include doped wide-bandgap semiconductors, for example, transparent conducting oxides such as indium tin oxide (ITO), gallium indium tin oxide (GITO), and zinc indium tin oxide (ZITO). In particular, ITO is a highly doped degenerate n+ semiconductor with an optical bandgap of approximately 3.2 eV, rendering it transparent to wavelengths greater than approximately 3900 Å. Another suitable metal substitute is the transparent conductive polymer polyanaline (PANI) and its chemical relatives. Metal substitutes may be further selected from a wide range of non-metallic materials, wherein the term “non-metallic” is meant to embrace a wide range of materials provided that the material is free of metal in its chemically uncombined form. When a metal is present in its chemically uncombined form, either alone or in combination with one or more other metals as an alloy, the metal may alternatively be referred to as being present in its metallic form or as being a “free metal”. Thus, the metal substitute electrodes of the present invention may sometimes be referred to as “metal-free” wherein the term “metal-free” is expressly meant to embrace a material free of metal in its chemically uncombined form. Free metals typically have a form of metallic bonding that results from a sea of valence electrons which are free to move in an electronic conduction band throughout the metal lattice. While metal substitutes may contain metal constituents they are “non-metallic” on several bases. They are not pure free-metals nor are they alloys of free-metals. When metals are present in their metallic form, the electronic conduction band tends to provide, among other metallic properties, a high electrical conductivity as well as a high reflectivity for optical radiation.

Embodiments of the present invention may include, as one or more of the transparent electrodes of the photosensitive optoelectronic device, a highly transparent, non-metallic, low resistance cathode such as disclosed in U.S. patent application Ser. No. 09/054,707 to Parthasarathy et al. (“Parthasarathy '707”), or a highly efficient, low resistance metallic/non-metallic compound cathode such as disclosed in U.S. Pat. No. 5,703,436 to Forrest et al. (“Forrest '436”). Each type of cathode is preferably prepared in a fabrication process that includes the step of sputter depositing an ITO layer onto either an organic material, such as CuPc, to form a highly transparent, non-metallic, low resistance cathode or onto a thin Mg:Ag layer to form a highly efficient, low resistance metallic/non-metallic compound cathode. Parthasarathy '707 discloses that an ITO layer onto which an organic layer had been deposited, instead of an organic layer onto which the ITO layer had been deposited, does not function as an efficient cathode.

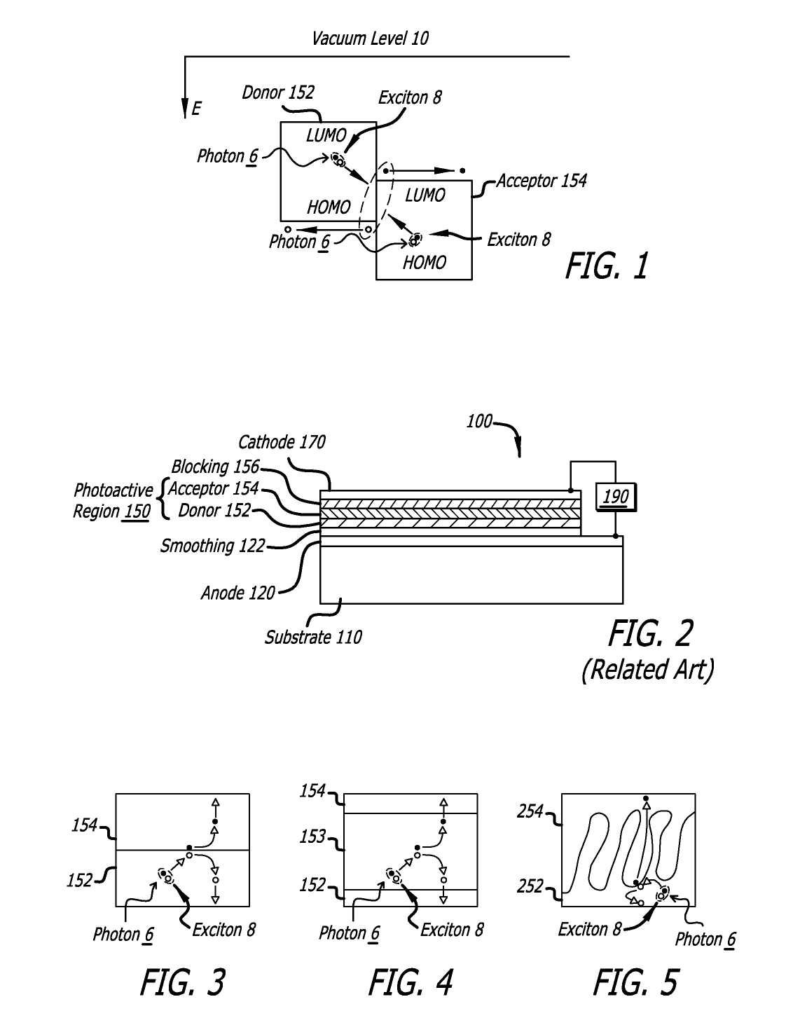

Herein, the term “cathode” is used in the following manner. In a non-stacked PV device or a single unit of a stacked PV device under ambient irradiation and connected with a resistive load and with no externally applied voltage, e.g., a solar cell, electrons move to the cathode from the adjacent photoconducting material. Similarly, the term “anode” is used herein such that in a solar cell under illumination, holes move to the anode from the adjacent photoconducting material, which is equivalent to electrons moving in the opposite manner. It will be noted that as the terms are used herein, anodes and cathodes may be electrodes or charge transfer layers. As illustrated in FIG. 2, anode 120 and cathode 170 are examples.

The donor-type material and the acceptor-type material form at least one photoactive region in which light is absorbed to form an exciton, which may subsequently dissociate into an electron and a hole in order to generate an electrical current. In FIG. 2, the photoactive region 150 comprises the donor material 152 and the acceptor material 154.

Organic materials for use in the photoactive region may include organometallic compounds, including cyclometallated organometallic compounds. The term “organometallic” as used herein is as generally understood by one of ordinary skill in the art and as given, for example, in Chapter 13 of Inorganic Chemistry (2nd Edition) by Gary L. Miessler and Donald A. Tarr, Prentice Hall (1999).

Preferably, the organic materials are purified. Organic materials may be purified by thermal gradient sublimation, as described in Forrest, Ultrathin Organic Films Grown by Organic Molecular Beam Deposition and Related Techniques, Chemical Review, 1997, 97(6), 1793-1896, which is incorporated herein by reference.

Preferably, the acceptor material comprises fullerene. The fullerenes useful in embodiments of this invention may have a broad range of sizes (number of carbon atoms per molecule). The term fullerene as used herein includes various cage-like molecules of pure carbon, including Buckminsterfullerene (C₆₀) and the related “spherical” fullerenes as well as carbon nanotubes. Fullerenes may be selected from those known in the art ranging from, for example, C₂₀-C₁₀₀₀. Preferably, the fullerene is selected from the range of C₆₀ to C₉₆. Most preferably the fullerene is C₆₀ or C₇₀. It is also permissible to utilize chemically modified fullerenes, provided that the modified fullerene retains acceptor-type and electron mobility characteristics.

The donor material comprises ClAlPc. ClAlPc can be synthesized, for example, from reacting phthalonitrile with aluminum trichloride. See Linsky et al., Inorganic Chemistry, 1980, 19, 3131.

Optionally, the donor-type material and the acceptor-type material form a donor-acceptor heterojunction. FIG. 2 shows an example of an organic photosensitive optoelectronic device 100 in which the photoactive region 150 comprises a donor-acceptor heterojunction with a donor layer 152 and an acceptor layer 154.

Examples of various types of donor-acceptor heterojunctions are shown in FIGS. 3-5. FIG. 3 illustrates a donor-acceptor bilayer forming a planar heterojunction. FIG. 4 illustrates a hybrid heterojunction including a mixed heterojunction 153 comprising a mixture of donor and acceptor materials. FIG. 5 illustrates an idealized “bulk” heterojunction. A bulk heterojunction, in the ideal photocurrent case, has a single continuous interface between the donor material 252 and the acceptor material 254, although multiple interfaces typically exist in actual devices. Mixed and bulk heterojunctions can have multiple donor-acceptor interfaces as a result of having plural domains of material. Domains that are surrounded by the opposite-type material (e.g., a domain of donor material surrounded by acceptor material) may be electrically isolated, such that these domains do not contribute to photocurrent. Other domains may be connected by percolation pathways (continuous photocurrent pathways), such that these other domains may contribute to photocurrent. The distinction between a mixed and a bulk heterojunction lies in degrees of phase separation between donor and acceptor materials. In a mixed heterojunction, there is very little or no phase separation (the domains are very small, e.g., less than a few nanometers), whereas in a bulk heterojunction, there is significant phase separation (e.g., forming domains with sizes of a few nanometers to 100 nm).

If a photoactive region includes a mixed layer (153) or bulk layers (252, 254) and one or both of the donor (152) and acceptor layers (154), the photoactive region is said to include a “hybrid” heterojunction. The arrangement of layers in FIG. 4 is an example. For additional explanation of hybrid heterojunctions, U.S. Patent Application Publication No. 2005/0224113 Al, entitled “High Efficiency Organic Photovoltaic Cells Employing Hybridized Mixed-Planar Heterojunctions” by Jiangeng Xue et al. is hereby incorporated by reference.

In general, planar heterojunctions have good carrier conduction, but poor exciton dissociation; a mixed layer has poor carrier conduction and good exciton dissociation, and a bulk heterojunction has good carrier conduction and good exciton dissociation, but may experience charge build-up at the end of the material “cul-de-sacs,” lowering efficiency. Unless otherwise stated, planar, mixed, bulk, and hybrid heterojunctions may be used interchangeably as donor-acceptor heterojunctions throughout the embodiments disclosed herein.

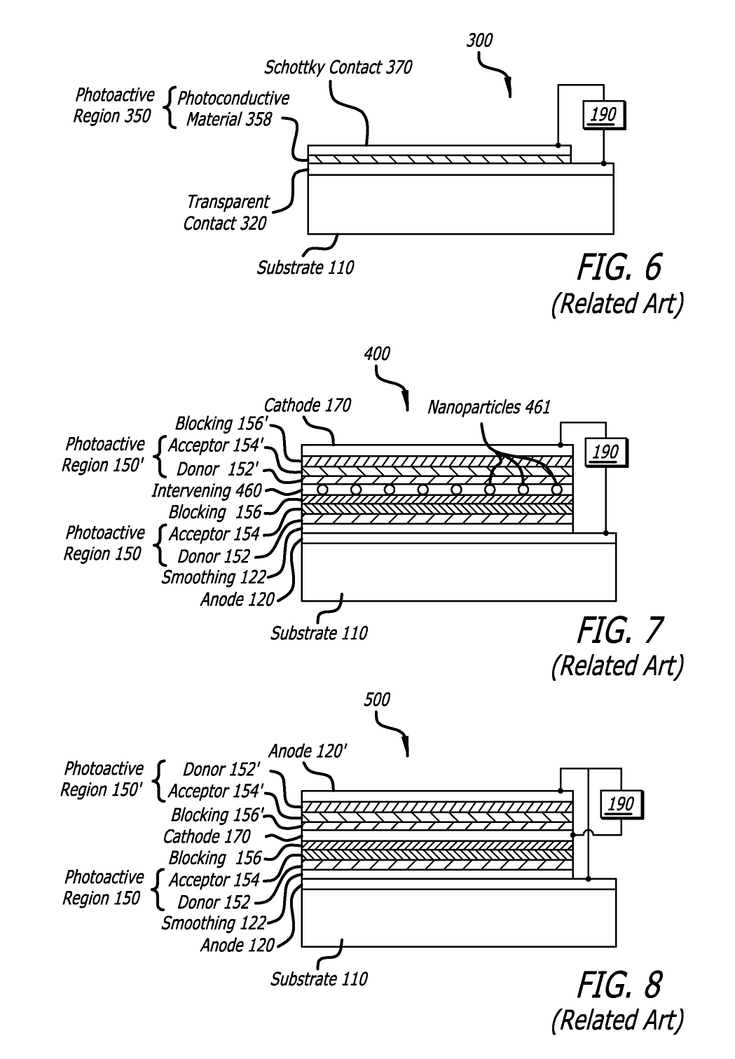

FIG. 6 shows an example of an organic photosensitive optoelectronic device 300 in which the photoactive region 350 is part of a Schottky-barrier heterojunction. Device 300 comprises a transparent contact 320, a photoactive region 350 comprising an organic photoconductive material 358, and a Schottky contact 370. The Schottky contact 370 is typically formed as a metal layer. If the photoconductive layer 358 is an ETL, a high work function metal such as gold may be used, whereas if the photoconductive layer is an HTL, a low work function metal such as aluminum, magnesium, or indium may be used. In a Schottky-barrier cell, a built-in electric field associated with the Schottky barrier pulls the electron and hole in an exciton apart. Generally, this field-assisted exciton dissociation is not as efficient as the disassociation at a donor-acceptor interface.

The devices as illustrated may be connected to an element 190. If the device is a photovoltaic device, element 190 is a resistive load which consumes or stores power. If the device is a photodetector, element 190 is a current detecting circuit which measures the current generated when the photodetector is exposed to light, and which may apply a bias to the device (as described for example in U.S. Patent Application Publication No. 2005-0110007 A1, by Forrest et al.). If the rectifying junction is eliminated from the device (e.g., using a single photoconductive material as the photoactive region), the resulting structures may be used as a photoconductor cell, in which case the element 190 is a signal detection circuit to monitor changes in resistance across the device due to the absorption of light. Unless otherwise stated, each of these arrangements and modifications may be used for the devices in each of the drawings and embodiments disclosed herein.

Organic layers may be fabricated using vacuum deposition, spin coating, organic vapor-phase deposition, inkjet printing and, other methods known in the art. Preferably, the vacuum deposition is conducted with the substrate a room temperature. Preferably, “room temperature” refers to a temperature of from about 15° C. to about 45° C.

Small-molecule mixed heterojunctions may be formed, for example, by co-deposition of the donor and acceptor materials using vacuum deposition or vapor deposition. Small-molecule bulk heterojunctions may be formed, for example, by controlled growth, co-deposition with post-deposition annealing, solution processing or switch OVPD forming nanocrystalline domain (e.g., as disclosed in U.S. patent application Ser. Nos. 11/561,448 and 11/880,210). Polymer mixed or bulk heterojunctions may be formed, for example, by solution processing of polymer blends of donor and acceptor materials.

Optionally, the thickness of the organic layer comprising ClAlPc is from about 0.1 Å to about 1000 Å. Preferably, the thickness is from about 100 Å to about 500 Å. More preferably, the thickness is about 500 Å.

Optionally, the growth rate of the organic layer comprising ClAlPc is from about 0.1 Å to about 1.5 Å/s. Preferably, the growth rate is about 0.5 Å/s.

Optionally, the organic photosensitive optoelectronic device of the present invention comprises a substrate. The substrate 110 may be any suitable substrate that provides desired structural properties. The substrate may be flexible or rigid, planar or non-planar. The substrate may be transparent, translucent or opaque. Rigid plastics and glass are examples of preferred rigid substrate materials. Flexible plastics and metal foils are examples of preferred flexible substrate materials.

The organic photosensitive optoelectronic device of the present invention comprises an exciton blocking layer (“EBL”). The exciton blocking nature of a material is not an intrinsic property (see U.S. Pat. No. 6,451,415). Whether a given material will act as an exciton blocker depends upon the relative HOMO and LUMO levels of the adjacent organic photosensitive material. Therefore, it is not possible to identify a class of compounds in isolation as exciton blockers without regard to the device context in which they may be used. However, a person skilled in the art would be able to identify whether a given material will function as an exciton blocker when used with a selected sets of materials to construct an organic photosensitive optoelectronic device. Examples of EBL 156 are described in U.S. Pat. No. 6,451,415 to Forrest et al., which is incorporated herein by reference for its disclosure related to EBLs. For instance, the exciton blocking layer can comprise 2,9-dimethyl-4,7-diphenyl-1,10-phenanthroline (BCP), 4,4′,4″-tris{N-(3-methylphenyl)-N-phenylamino}triphenylamine (m-MTDATA) or polyethylene dioxythiophene (PEDOT). Additional background explanation of EBLs may also be found in Peumans et al., Efficient Photon Harvesting at High Optical Intensities in Ultrathin Organic Double-Heterostructure Photovoltaic Diodes, Applied Physics Letters 76, 2650-52 (2000). EBLs reduce quenching by preventing excitons from migrating out of the donor and/or acceptor materials.

Optionally, the organic photosensitive optoelectronic device of the present invention comprises an anode-smoothing layer. The anode-smoothing layer 122 may be situated between the anode layer 120 and the donor layer 152. Anode-smoothing layers are described in U.S. Pat. No. 6,657,378 to Forrest et al., incorporated herein by reference for its disclosure related to this feature.

Optionally, the organic photosensitive optoelectronic device of the present invention comprises transparent charge transfer layers, electrodes, or charge recombination zones. A charge transfer layer may be organic or inorganic, and may or may not be photoconductively active. A charge transfer layer is similar to an electrode, but does not have an electrical connection external to the device and only delivers charge carriers from one subsection of an optoelectronic device to the adjacent subsection. A charge recombination zone is similar to a charge transfer layer, but allows for the recombination of electrons and holes between adjacent subsections of an optoelectronic device. A charge recombination zone may include semi-transparent metal or metal substitute recombination centers comprising nanoclusters, nanoparticles, and/or nanorods, as described for example in U.S. Pat. No. 6,657,378 to Forrest et al.; U.S. Patent Application Publication No. 2006-0032529 A1, entitled “Organic Photosensitive Devices” by Rand et al.; and U.S. Patent Application Publication No. 2006-0027802 A1, entitled “Stacked Organic Photosensitive Devices” by Forrest et al., each of which incorporated herein by reference for its disclosure of recombination zone materials and structures. A charge recombination zone may or may not include a transparent matrix layer in which the recombination centers are embedded. A charge transfer layer, electrode, or charge recombination zone may serve as a cathode and/or an anode of subsections of the optoelectronic device. An electrode or charge transfer layer may serve as a Schottky contact.

Optionally, the organic photosensitive optoelectronic device of the present invention comprises multiple heterojunctions in tandem, as described, for example, in Yakimov and Forrest, High Photovoltage Multiple-Heterojunction Organic Solar Cells Incorporating Interfacial Metallic Nanoclusters, Applied Physics Letters, 2002, 80(9), 1667-1669.

FIGS. 7 and 8 illustrate examples of tandem devices including transparent charge transfer layers, electrodes, and charge recombination zones. In device 400 in FIG. 7, photoactive regions 150 and 150′ are stacked electrically in series with an intervening conductive region 460. As illustrated without external electrical connections, intervening conductive region 460 may be a charge recombination zone or may be a charge transfer layer. As a recombination zone, region 460 comprises recombination centers 461 with or without a transparent matrix layer. If there is no matrix layer, the arrangement of material forming the zone may not be continuous across the region 460. Device 500 in FIG. 8 illustrates photoactive regions 150 and 150′ stacked electrically in parallel, with the top cell being in an inverted configuration (i.e., cathode-down). In each of FIGS. 7 and 8, the photoactive regions 150 and 150′ and blocking layers 156 and 156′ may be formed out of the same respective materials, or different materials, depending upon the application. Likewise, photoactive regions 150 and 150′ may be a same type (i.e., planar, mixed, bulk, hybrid) of heterojunction, or may be of different types.

In each of the devices described above, layers may be omitted, such as the exciton blocking layers. Other layers may be added, such as reflective layers or additional photoactive regions. The order of layers may be altered or inverted. A concentrator or trapping configuration may be employed to increase efficiency, as disclosed, for example in U.S. Pat. No. 6,333,458 to Forrest et al. and U.S. Pat. No. 6,440,769 to Peumans et al., which are incorporated herein by reference. Coatings may be used to focus optical energy into desired regions of a device, as disclosed, for example in US Patent Application Publication No. 2005-0266218 A1, entitled “Aperiodic Dielectric Multilayer Stack” by Peumans et al., which is incorporated herein by reference. In the tandem devices, transparent insulative layers may be formed between cells, with the electrical connection between the cells being provided via electrodes. Also in the tandem devices, one or more of the photoactive regions may be a Schottky-barrier heterojunction instead of a donor-acceptor heterojunction. Arrangements other than those specifically described may be used.

Advantages of using ClAlPc in the photosensitive optoelectronic devices of the present invention are that the absorption peak at about 750 nm gives photo-response out into the near-IR range; and that very low dark current can be obtained.

### Experimental Results

As described below, the performance of photosensitive optoelectronic devices comprising ClAlPc as a donor material was studied as a function of the thickness and growth rate of the ClAlPc layer and compared with those comprising CuPc as a donor material.

Organic materials were purified by thermal gradient sublimation (3 cycles for C₆₀ and 1 cycle for all other materials) prior to being loaded in a thermal evaporation chamber with a base pressure of 5×10⁻⁷ Torr. ITO-coated glass substrates with a sheet resistance of 15Ω/□ were solvent cleaned and ultraviolet ozone treated as described in Saltzman et al, The Effects of Copper Phthalocyanine Purity on Organic Solar Cell Performance, Organic Electronics, 2005, 6(5-6), 242-246.

Absorption spectra were measured on 100-1000 Å thick films thermally deposited on quartz substrates. Scanning electron microcopy (SEM) and atomic force microscopy (AFM) were used to image 200 Å thick films thermally deposited at 0.1, 0.5, and 1.5 Å/s, on both ITO-coated glass and native oxide coated Si substrates. X-ray diffraction (XRD) data were collected in the Bragg-Brentano geometry for 1000 Å thick films of ClAlPc thermally deposited at 1 Å/s on ITO-coated glass substrates. Ultraviolet photoelectron spectroscopy was used to determine the ionization potential of a ClAlPc film grown under ultrahigh vacuum by organic molecular beam deposition (as described in Forrest, Ultrathin Organic Films Grown by Organic Molecular Beam Deposition and Related Techniques, Chemical Review, 1997, 97(6), 1793-1896) at 1.5 Å/s on thermally deposited Ag on Si.

The device structure grown by thermal evaporation consists of an ITO anode, a 200 Å thick film of ClAlPc as donor, a 400 Å thick film of C₆₀ as acceptor, a 100 Å thick film of bathocuprine (“BCP”) as the exciton blocking layer, and Ag as the cathode. A vacuum break to an inert nitrogen environment occurred between growth of the BCP layer and the Ag cathode to attach a shadow mask consisting of an array of 1 mm diameter openings. The cells were tested in air using a semiconductor parameter analyzer, and illuminated with an AM1.5 G solar simulator using a 150 W xenon arc lamp. Neutral density filters were used to vary the intensity of the incident light.

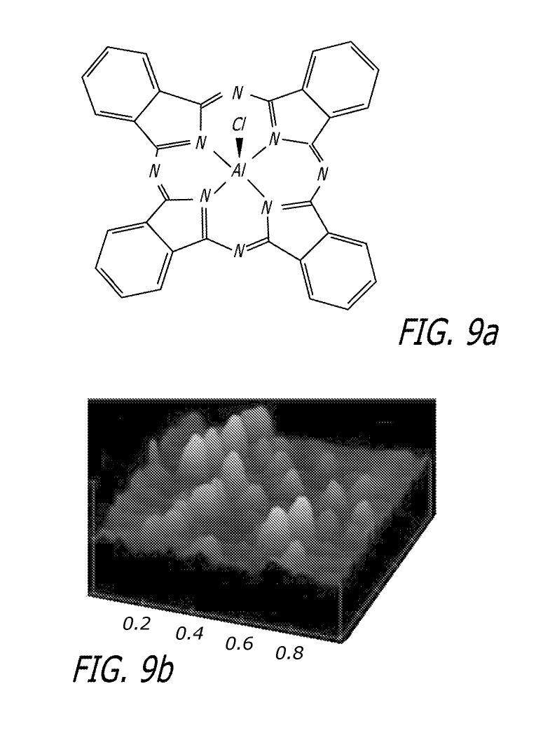

FIG. 9(a) shows the molecular structural formula of ClAlPc. The Al atom, in the center of the phthalocyanine ring, is bonded to an out-of-plane Cl atom. This nonplanar structure influences the molecular packing and hence film morphology; a hypothesized slipped-deck stacking in a monoclinic lattice has been reported in Whitlock et al., Investigations of Materials and Device Structures for Organic Semiconductor Solar Cells, Optical Engineering, 1993, 32(8), 1921-1934.

Ultraviolet photoelectron spectroscopy was used to determine the ionization potential (and hence the HOMO position) relative to vacuum at −5.4±0.1 eV, compared to CuPc at −5.3±0.1 eV. XRD showed no ClAlPc diffraction peaks, indicating an amorphous film, or lack of long-range order.

SEM and AFM images of films grown at 0.1, 0.5, and 1.5 Å/s both on ITO-coated glass and on oxidized Si displayed similar morphologies and surface roughnesses. FIG. 9(b) shows an AFM image of a 200 Å thick film of ClAlPc on ITO-coated glass deposited at a rate of 0.5 Å/s. Measurements of ClAlPc films deposited on ITO-coated glass substrates yield root mean square surface roughnesses of 57, 53, and 34 Å with respect to the increasing growth rate. Features of approximately 100 nm in diameter are observed on the film surfaces in both SEM and AFM images.

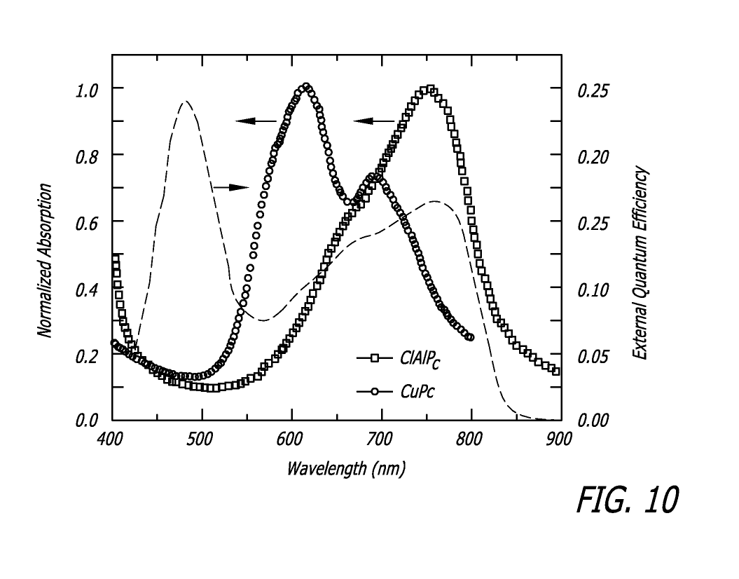

FIG. 10 shows the absorption spectrum of ClAlPc along with that of CuPc for reference. The absorption for ClAlPc is significantly redshifted, peaking at λ=755 nm, compared to λ=620 nm for CuPc. Although previous work with nonplanar IR absorbing materials has shown the absorption spectral shape depends on film thickness due to molecular aggregation and dimer formation (see Rand, et al., Organic Solar Cells with Sensitivity Extending into the Near Infrared, Applied Physics Letters, 2005, 87, 233508), the present inventors found no significant peak shift or change in shape between thicknesses of 100 and 1000 Å. Absorption spectra were also measured for films grown at rates varying from 0.1 to 1.5 Å/s, and again no significant differences were observed.

The external quantum efficiency is also shown for an ITO/200 Å ClAlPc/400 Å C₆₀/100 Å BCP/Ag organic photovoltaic cell in FIG. 10. As expected from the absorption in the near IR, the photoresponse extends to λ=800 nm. The C₆₀ response is apparent at short wavelengths, peaking at λ=480 nm.

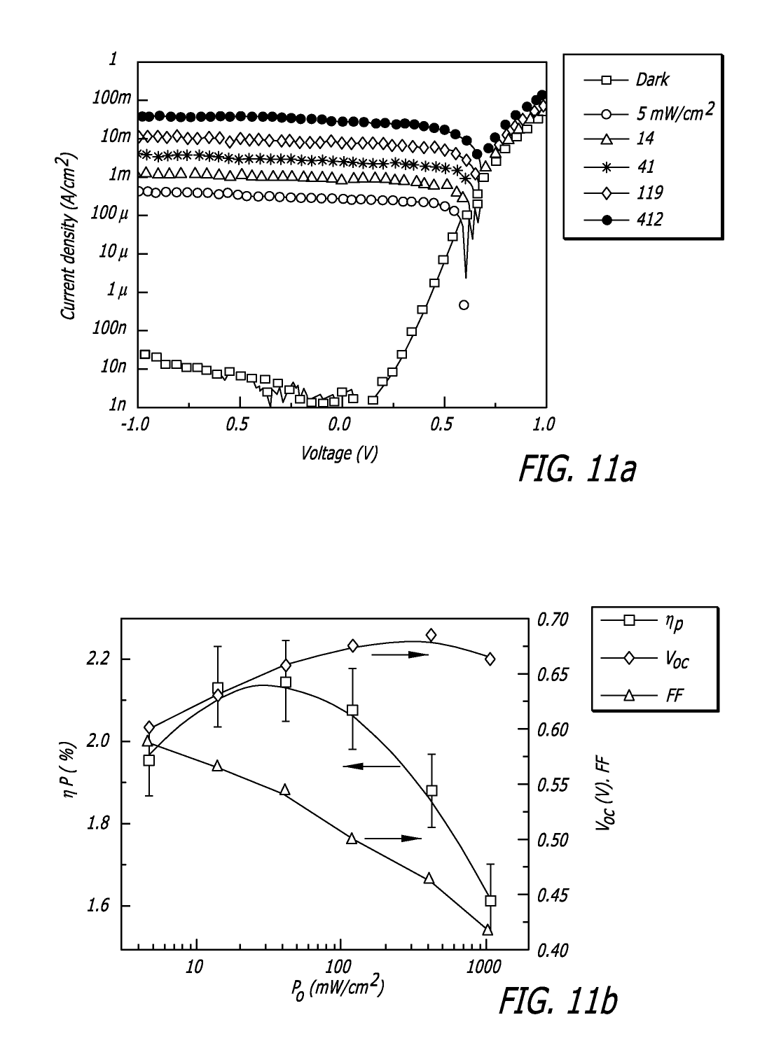

Current density—voltage curves under various levels of illumination and in the dark are shown in FIG. 11(a). The growth rate of ClAlPc to achieve optimal device performance was 0.5 Å/s, although device parameters showed significant run-to-run variation, possibly due to impurities or materials degradation from heating during evaporation. Under simulated AM1.5 G illumination at 119 mW/cm², the device open circuit voltage was V_{OC}=0.68±0.01 V, fill factor (FF)=0.50±0.04, and responsivity (J_{SC}/P₀)=0.062±0.007 A/W, leading to η_{P}=2.1±0.1%, uncorrected for spectral mismatch between the simulated spectrum and that of the sun (see ASTM International Standard Test Method E 973-02; Emery, K., IEEE Trans. Electron Devices, 1999, 46, 1928).

FIG. 11(b) shows the dependence of η_{P}, V_{OC}, and FF on incident optical power density P₀. The data presented in FIG. 11 and Table 1 represent the best devices grown under the stated conditions. While these results were reproduced during initial studies, after several months of storing the source materials in air and under illumination, device performance noticeably degraded.

TABLE 1
Organic Photovoltaic Cell Results

| ClAlPc | | | | | Dark current |
|---|---|---|---|---|---|
| growth rate | V_{OC} | J_{SC}/P₀ | | | at −1 V |
| (Å/s) | (V)^{a} | (A/W) | FF | η_{P} (%) | (Å/cm²) |
| 0.1 | 0.49 | 0.064 | 0.54 | 1.7 ± 0.1 | 1.8 × 10⁻⁷ |
| 0.5 | 0.68 | 0.062 | 0.50 | 2.1 ± 0.1 | 2.4 × 10⁻⁸ |
| 1.5 | 0.71 | 0.050 | 0.50 | 1.8 ± 0.1 | 5.3 × 10⁻⁸ |
| CuPc control | 0.51 | 0.060 | 0.58 | 1.8 ± 0.1 | 1.4 × 10⁻⁶ |

Open-circuit voltage, responsivity, fill factor, and power conversion efficiency measured under simulated AM1.5G, 1 sun intensity illumination.

The dark current under reverse bias is J_{D}=2.4×10⁻⁸ A/cm² at −1 V. The exceptionally low J_{D} results in an increased V_{OC} since V_{OC}=(kT/q)ln((I_{L}/I_{S})+1)≈(kT/q)ln(I_{L}/I_{S}), where k is the Boltzmann constant, T is the temperature, q is the elementary charge, I_{L}, is the photocurrent, and I_{S} is the diode reverse saturation current. See Sze, Physics of Semiconductor Devices, 2nd ed. (Wiley, New York, 1981), p. 794. An increase in V_{OC} is also expected due to the 0.1±0.1 eV larger interface energy gap (defined as the difference in energy between the acceptor lowest unoccupied molecular orbital of the acceptor and the HOMO energy of the donor), as compared to that of the CuPc/C₆₀ system, consistent with previous analysis. See Mutolo et al., Enhanced Open-Circuit Voltage in Subphthalocyanine/C₆₀ Organic Photovoltaic Cells, Journal of American Chemistry Society, 2006, 128(25), 8108-8109; Rand and Burk, Offset Energies at Organic Semiconductor Heterojunctions and Their Influence on the Open-Circuit Voltage of Thin-Film Solar Cells, Physical Review B, 2007, 75, 115327.

Device performance was found to vary with the ClAlPc growth rate, although no significant differences were observed in the film microstructures or absorption. Table 1 summarizes the values of each performance parameter at each growth rate, as well as analogous CuPc-based devices. With increasing growth rate, V_{OC} of the ClAlPc devices increases from 0.49±0.02 to 0.71±0.01 V. Conversely, J_{SC}/P₀ falls from 0.064±0.004 to 0.050±0.004 A/W, whereas FF remains relatively unchanged at 0.50±0.04. Finally, η_{P} first increases and then falls off with rate, peaking at η_{P}=2.1±0.1% at a growth rate of 0.5 Å/s. In contrast, the dark current at a reverse bias of −1 V decreases with increasing growth rate, with a minimum value of 2.4×10⁻⁸ A/cm² at 0.5 Å/s, two orders of magnitude lower than for analogous CuPc-based devices.

Note that the CuPc/C₆₀ device parameters of FF, J_{SC}/P₀, and η_{P} are significantly lower than the highest reported values in Peumans and Forrest, Very-High-Efficiency Double-Heterostructure Copper Phthalocyanine/C₆₀ Photovoltaic Cells, Applied Physics Letters, 2001, 79(1), 126-128, Peumans et al., Small Molecular Weight Organic Thin-film Photodetectors and Solar Cells, Journal of Applied Physics, 2003, 93(7), 3693-3723, and Xue et al., 4.2% Efficient Organic Photovoltaic Cells with Low Series Resistances, Applied Physics Letters, 2004, 84(16), 3013-3015. The present inventors have found the device performance to be strongly dependent on materials purity, which may account for reduced performance in this case. See Saltzman et al, The Effects of Copper Phthalocyanine Purity on Organic Solar Cell Performance, Organic Electronics, 2005, 6(5-6), 242-246. Nonetheless, V_{OC} and η_{P} are significantly increased relative to the CuPc control. Additionally, the FF and responsivities of both structures are similar, indicating that ClAlPc/C₆₀ elements are candidates for use in tandem cells to achieve spectral coverage into the IR.

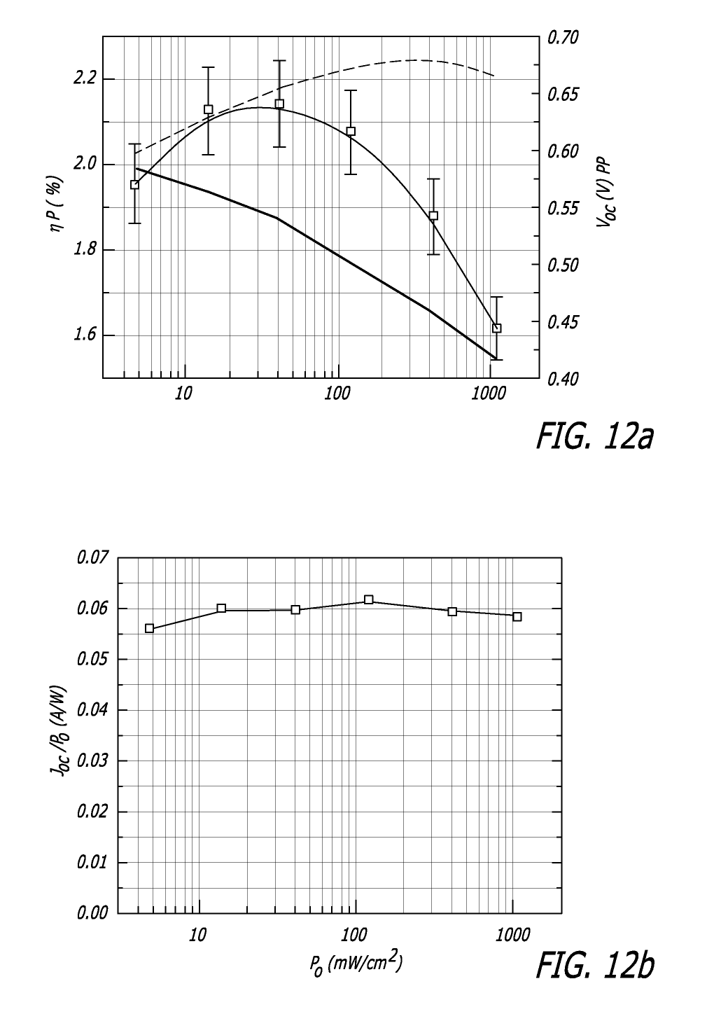

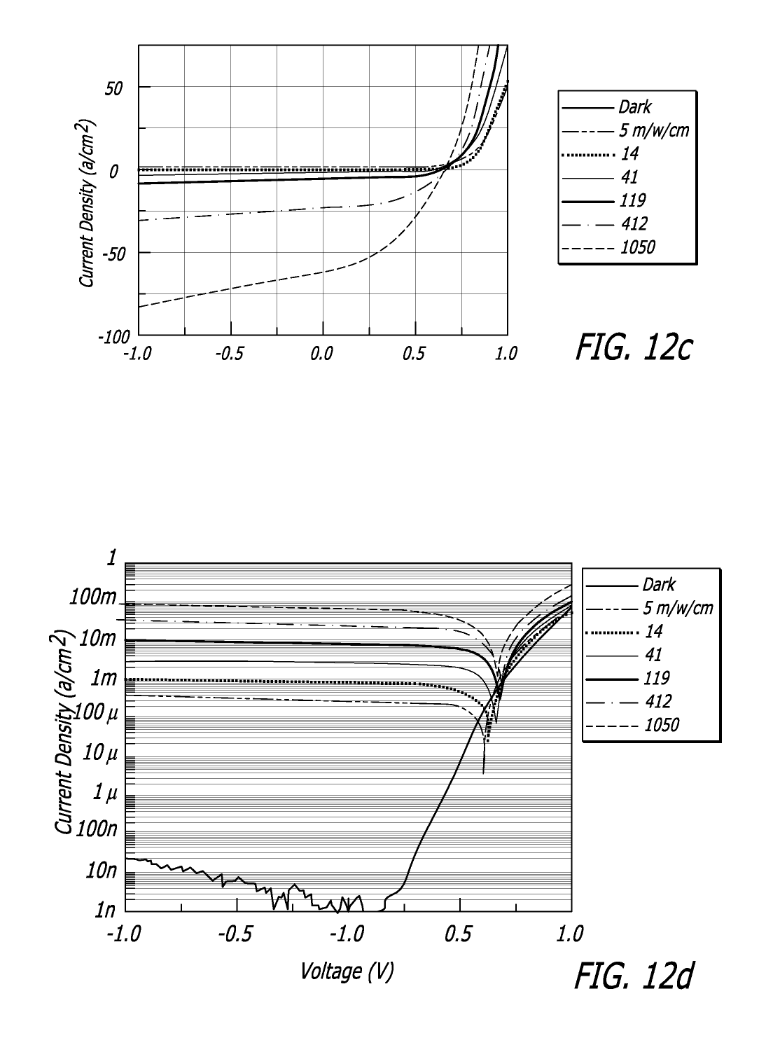

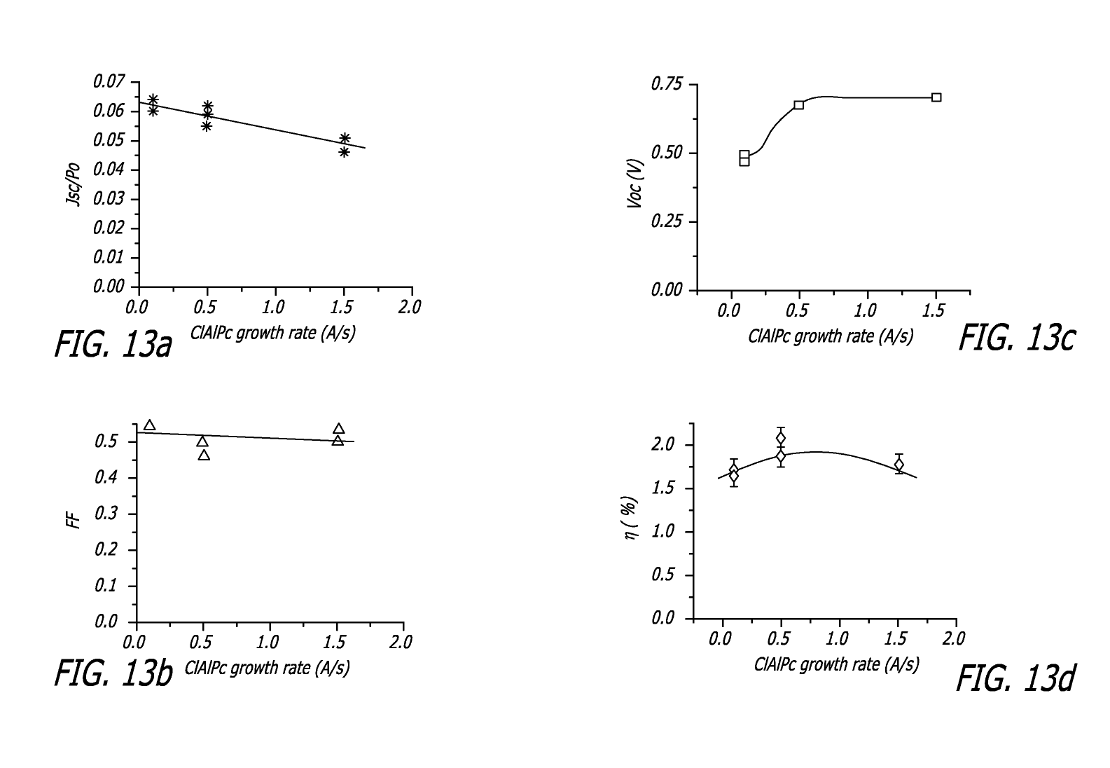

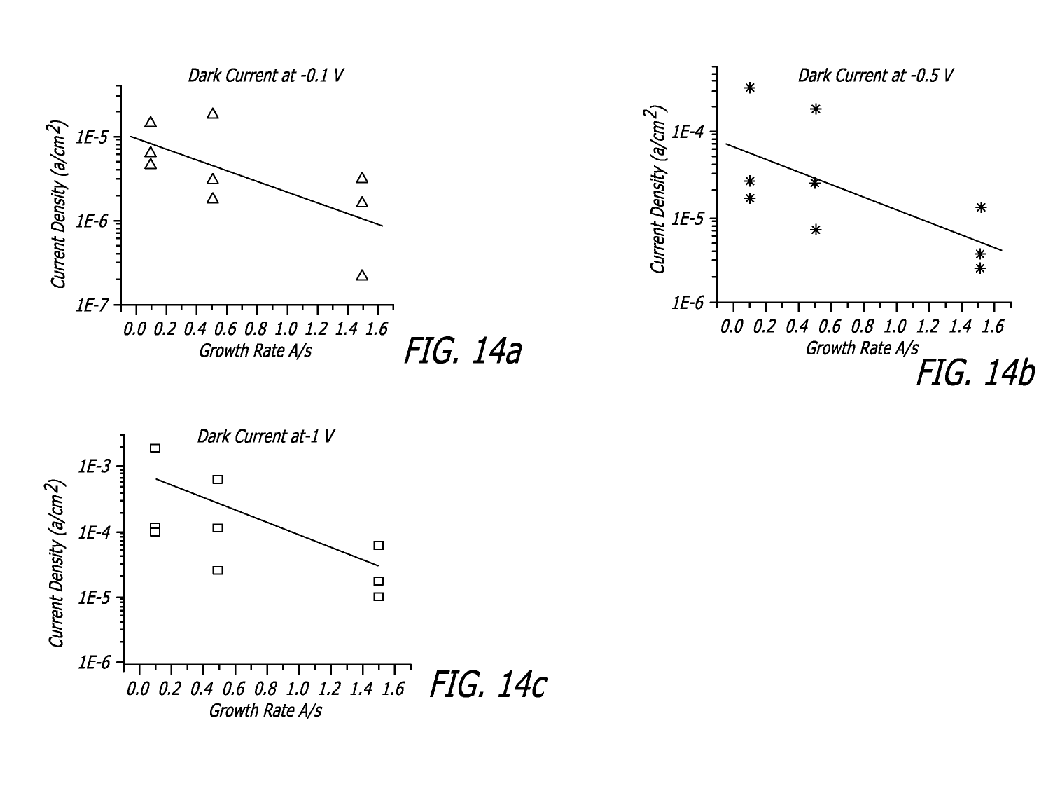

The performances of the ITO/200 Å ClAlPc/400 Å C₆₀/100 Å BCP/Ag organic photovoltaic cell are also shown in FIGS. 12, 13 and 14.

In conclusion, ClAlPc has been shown to be useful in organic photovoltaic cells with response extending into the near IR. This material displays an enhanced V_{OC} when compared to a CuPc/C₆₀ control device. The ionization potential of ClAlPc is 0.1 eV larger than that of CuPc, thus leading to a concomitant increase in V_{OC}. Finally, the low dark currents under reverse bias for these cells indicate that ClAlPc may also be useful in low noise photodetector applications

Specific examples of the invention are illustrated and/or described herein. However, it will be appreciated that modifications and variations of the invention are covered by the above teachings and within the purview of the appended claims without departing from the spirit and scope of the invention.

We claim:

1. An organic photosensitive optoelectronic device comprising:
(i) first electrode and second electrode, wherein at least one of the first electrode and the second electrode is transparent;
(ii) organic photoactive materials disposed between the first electrode and the second electrode, comprising:
(a) a first organic semiconductor material; and
(b) a second organic semiconductor material,
wherein the first organic semiconductor material comprises at least one donor material relative to the second organic semiconductor material with the second organic semiconductor material comprising at least one acceptor material, or the first organic semiconductor material comprises at least one acceptor material relative to the second organic semiconductor material with the second organic semiconductor material comprising at least one donor material, wherein the donor material comprises ClAlPc, and wherein the first organic semiconductor material is in direct contact with the second organic semiconductor material; and
(iii) at least one exciton blocking layer between the two electrodes and adjacent to at least one of the two electrodes.

2. The device of claim 1, wherein the organic semiconductor materials are purified.

3. The device of claim 1, wherein the at least one acceptor material comprises C₆₀.

4. The device of claim 1, wherein the donor material comprising ClAlPc is in a layer having a thickness of about 0.1 Å to about 1000 Å.

5. The device of claim 4, wherein the thickness is from about 100 Å to about 500 Å.

6. The device of claim 5, wherein the thickness is about 500 Å.

7. The device of claim 1, wherein the blocking layer comprises BCP, and wherein BCP is 2,9-dimethyl-4,7-diphenyl-1,10-phenanthroline or bathocupoine.

8. The device of claim 7 comprising ITO/ClAlPc/C₆₀/BCP/Ag, wherein ITO is indium tin oxide, and wherein the ITO layer and the Ag layer are electrode layers and the at least one acceptor material comprises C₆₀.

9. The device of claim 8 comprising ITO/ClAlPc (200 Å at 0.5 Å/s)/C₆₀ (400 Å)/BCP (100 Å)/Ag.

10. The device of claim 8, wherein the ITO is in an anode layer and the Ag is in a cathode layer.

11. The device of claim 1, wherein the device is an organic photovoltaic acid.

12. The device of claim 1, wherein the device is a photoconductor cell.

13. The device of claim 1, wherein the device is a photodetector or photosensor.

14. A method of fabricating the organic photosensitive optoelectronic device of claim 1, comprising:
(I) depositing a first organic semiconductor material on a first electrode;
(II) depositing a second organic semiconductor material on the product of step (I);
(III) depositing a second electrode on the product of step (II),
wherein the first organic semiconductor material comprises at least one donor material relative to the second organic semiconductor material with the second organic semiconductor material comprising at least one acceptor material, or the first organic semiconductor material comprises at least one acceptor material relative to the second organic semiconductor material with the second organic semiconductor material comprising at least one donor material, wherein the at least one donor material comprises ClAlPc; and
(IV) putting at least one exciton blocking layer between the two electrodes and adjacent to at least one of the two electrodes.
